(19) United States
(12) Patent Application Publication
(10) Pub. No.: US 2025/0276772 A1
(43) Pub. Date: Sep. 4, 2025

(54) Vision System For Maritime Vehicle

(71) Applicant: SARONIC TECHNOLOGIES, Austin, TX (US)

(72) Inventors: Dana Wieland, Austin, TX (US); Ryan Howard, Austin, TX (US); Trish Anne Roque, Austin, TX (US); Douglas Lambert, Austin, TX (US)

(21) Appl. No.: 19/070,345

(22) Filed: Mar. 4, 2025

Related U.S. Application Data
(60) Provisional application No. 63/561,301, filed on Mar. 4, 2024.

(51) Int. Cl. B63B 79/15; G03B 30/00; G03B 35/10; H04N 13/204; H04N 23/20; H04N 23/45; H04N 23/54; H04N 23/90; H05K 7/20

(52) U.S. Cl. CPC B63B 79/15; G03B 30/00; G03B 35/10; H04N 13/204; H04N 23/20; H04N 23/45; H04N 23/54; H04N 23/90; H05K 7/2039

(57) ABSTRACT

A camera module for a maritime vehicle. The camera module includes a frame comprising first and second openings, first and second windows disposed in the frame immediately adjacent the first and second openings, respectively, a retention plate coupled to the frame and configured to retain the first and second windows in the frame immediately adjacent the first and second openings, a stereo camera disposed within the frame, the stereo camera disposed immediately adjacent the first opening, and an infrared (IR) camera disposed within the frame, the IR camera disposed immediately adjacent the second opening.

### CROSS-REFERENCE TO RELATED APPLICATION

The present application claims priority to U.S. Provisional Patent Application No. 63/561,301, titled “Vision System for Maritime Vehicle,” and filed on Mar. 4, 2024, the contents of which are hereby incorporated by reference in its entirety.

### FIELD OF THE DISCLOSURE

The present disclosure generally relates to maritime vehicles and more specifically to a vision system for a maritime vehicle.

### BACKGROUND OF THE DISCLOSURE

Maritime vehicles, or vehicles designed for use on or in the water, are commonly used for transportation, recreation, defense, scientific research, and other purposes. Examples of maritime vehicles include boats, watercraft, submarines, and amphibious vehicles. Maritime vehicles can be manned (i.e., operated by an onboard human) or unmanned, and unmanned maritime vehicles can be remotely controlled or can be autonomous.

### SUMMARY

A camera module for a maritime vehicle. The camera module includes a frame comprising first and second openings, first and second windows disposed in the frame immediately adjacent the first and second openings, respectively, a retention plate coupled to the frame and configured to retain the first and second windows in the frame immediately adjacent the first and second openings, a stereo camera disposed within the frame, the stereo camera disposed immediately adjacent the first opening, and an infrared (IR) camera disposed within the frame, the IR camera disposed immediately adjacent the second opening.

### BRIEF DESCRIPTION OF THE DRAWINGS

The features of this invention which are believed to be novel are set forth with particularity in the appended claims. The invention may be best understood by reference to the following description taken in conjunction with the accompanying drawings, in which like reference numerals identify like elements in the several FIGS., in which:

FIG. 1A is a top perspective view of an example of a maritime vehicle constructed in accordance with the teachings of the present disclosure;

FIG. 1B is a front view of the maritime vehicle of FIG. 1A;

FIG. 1C is a rear view of the maritime vehicle of FIG. 1A;

FIG. 1D is a bottom perspective view of the maritime vehicle of FIG. 1A;

FIG. 1E is a side view of the maritime vehicle of FIG. 1A;

FIG. 1F is similar to FIG. 1A, but with the cap and various components of the maritime vehicle removed for illustrative purposes;

FIG. 1G is similar to FIG. 1F, but with additional components of the maritime vehicle removed for illustrative purposes;

FIG. 1H is a rear, perspective view of the maritime vehicle of FIG. 1F;

FIG. 1I is a first cross-sectional view taken along line I-I in FIG. 1A;

FIG. 1J is a second cross-sectional view taken along line J-J in FIG. 1A;

FIG. 1K is similar to FIG. 1A, but with the latching assembly of the maritime vehicle partially removed for illustrative purposes;

FIG. 2A is a front, perspective view of one example of a vision system that can be employed in the maritime vehicle of FIGS. 1A-1K;

FIG. 2B is another front, perspective view of the vision system of FIG. 2A;

FIG. 2C is a front, perspective view of a housing of the vision system of FIG. 2A;

FIG. 2D is an exploded view of the housing of FIG. 2C;

FIG. 2E is another front, perspective view of the vision system of FIG. 2A;

FIG. 2F is a rear, perspective view of a camera module and an electronics plate of the vision system of FIG. 2A;

FIG. 2G is a front, exploded view of the camera module;

FIG. 2H is a rear, exploded view of the camera module;

FIG. 2I is a front, perspective view of a retention plate of the camera module;

FIG. 2J is a rear view of FIG. 21;

FIG. 2K is a top view of FIG. 21;

FIG. 2L is a cross-sectional view taken along line K-K in FIG. 2K;

FIG. 2M is a perspective view of an electro-optical camera of the vision system of FIG. 2A;

FIG. 2N is a perspective view of a bracket for the electro-optical camera of FIG. 2M;

FIG. 2O is a perspective view of a bracket for infrared cameras of the vision system of FIG. 2A;

FIG. 2P is a front, perspective view of the electronics plate of the vision system of FIG. 2A;

FIG. 2Q is a rear, perspective view of the electronics plate;

FIG. 2R illustrates the electronics plate being coupled to the housing;

FIG. 2S is a cross-sectional view of the vision system of FIG. 2A;

FIG. 2T is an exploded view of the vision system of FIG. 2A;

FIG. 2U is a front, perspective view showing the orientation of the vision system of FIG. 2A when installed in the maritime vehicle of FIGS. 1A-1K;

FIG. 2V is a side view of FIG. 2U;

FIG. 2W is a rear, perspective view of FIG. 2U;

FIG. 2X is a top view of the field of vision of the vision system of FIG. 2A when in operation.

FIGS. 2Y and 2Z are side views of the field of vision of the vision system of FIG. 2A when in operation.

### DETAILED DESCRIPTION

The present disclosure is directed to a maritime vehicle that is primarily intended for use for military purposes (e.g., for naval defense, patrolling waters and enforcing laws, reconnaissance, naval exploration, monitoring) but can also be used for other purposes if desired. The maritime vehicle is small(er), durable, and configured to quickly, efficiently, and stealthily traverse a body of water once dispatched (e.g., from other maritime vehicles, beachheads, or an airdrop). The maritime vehicle is modular, with components that can be flexibly altered, removed, or added as desired in accordance with the mission of the maritime vehicle. The maritime vehicle can collaborate with other similar maritime vehicles and/or military assets when necessary. The maritime vehicle is preferably unmanned and autonomous though need not be.

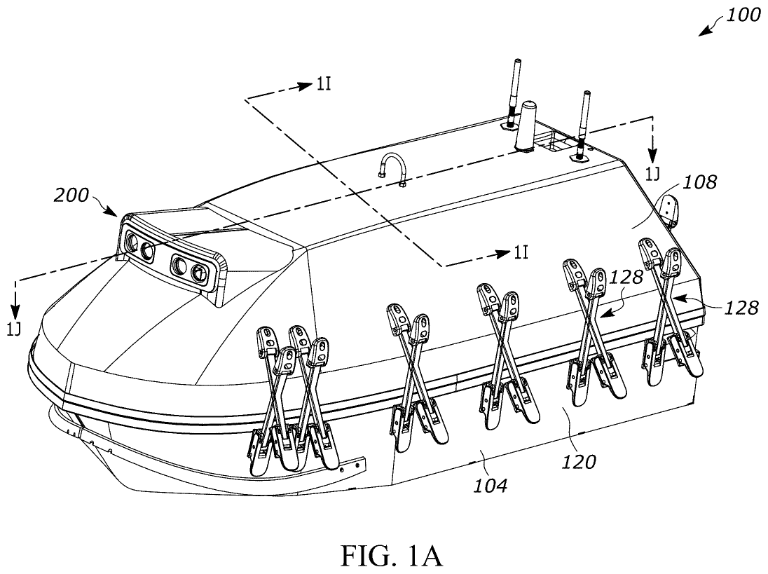

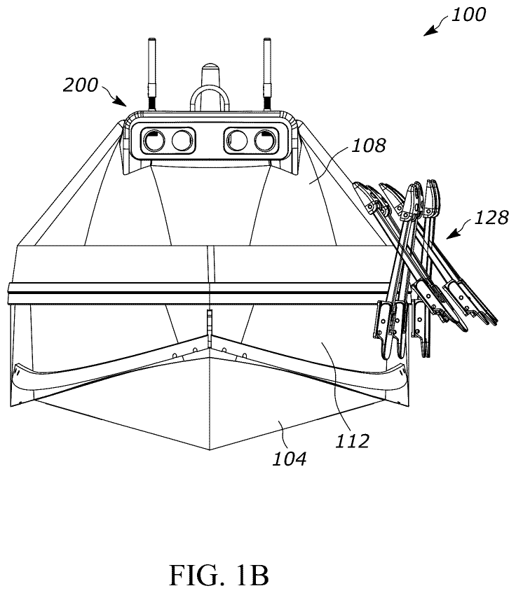

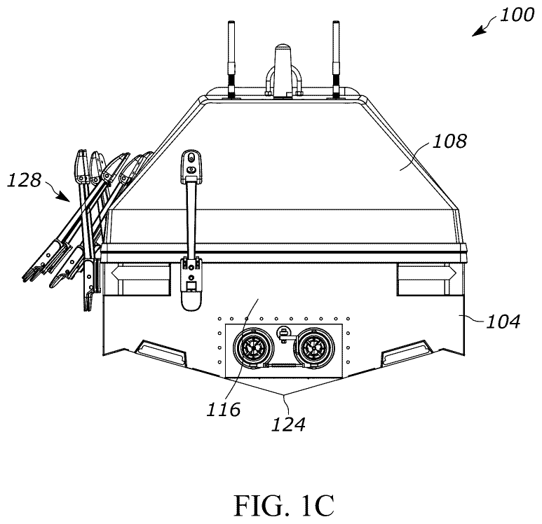

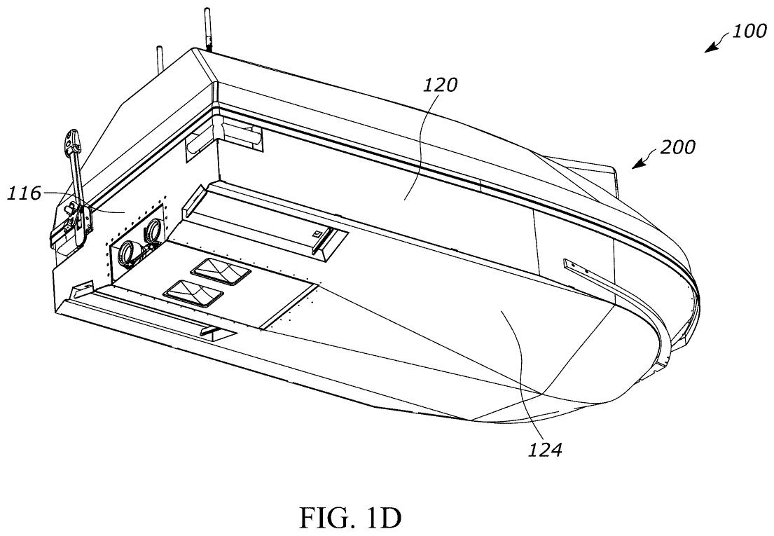

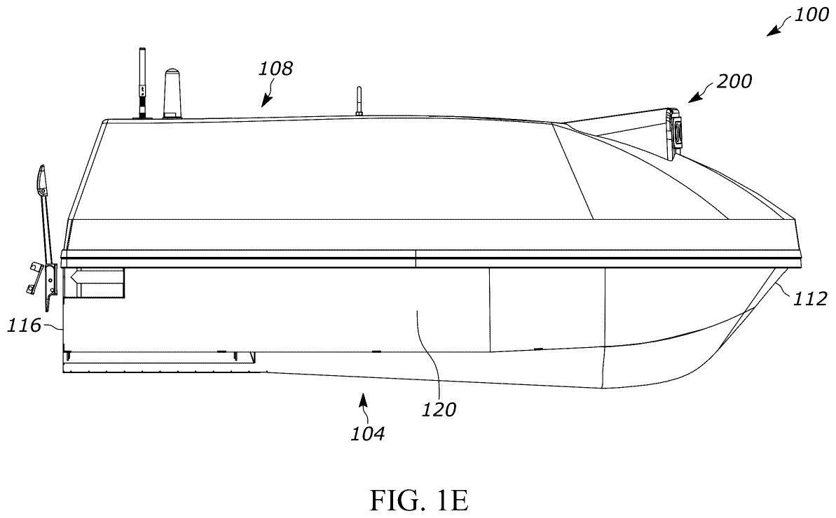

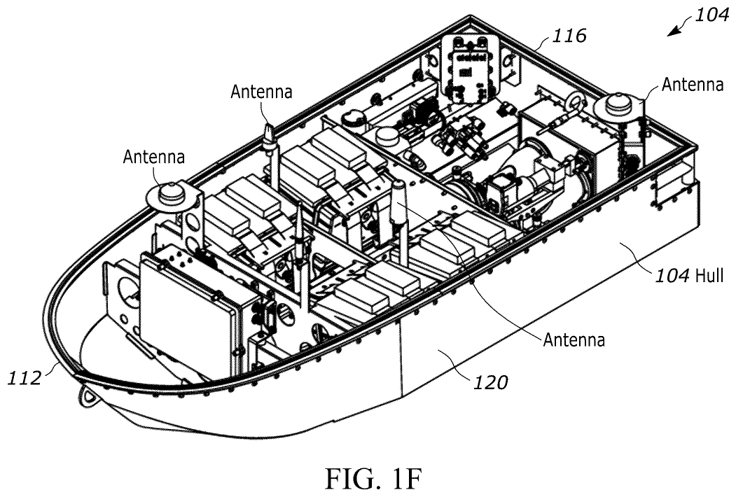

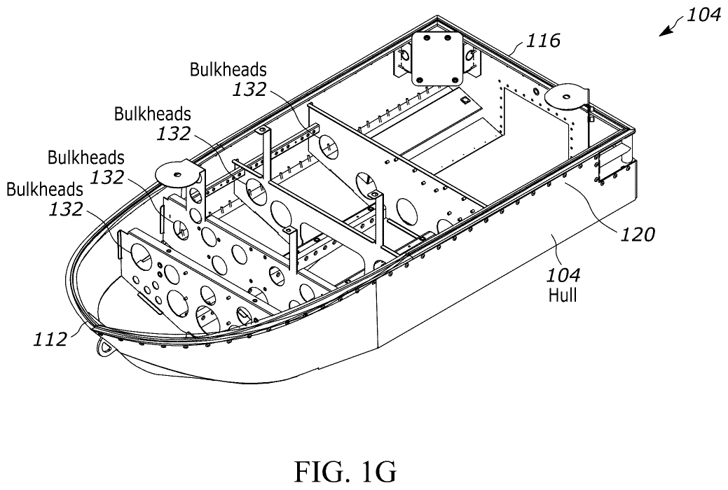

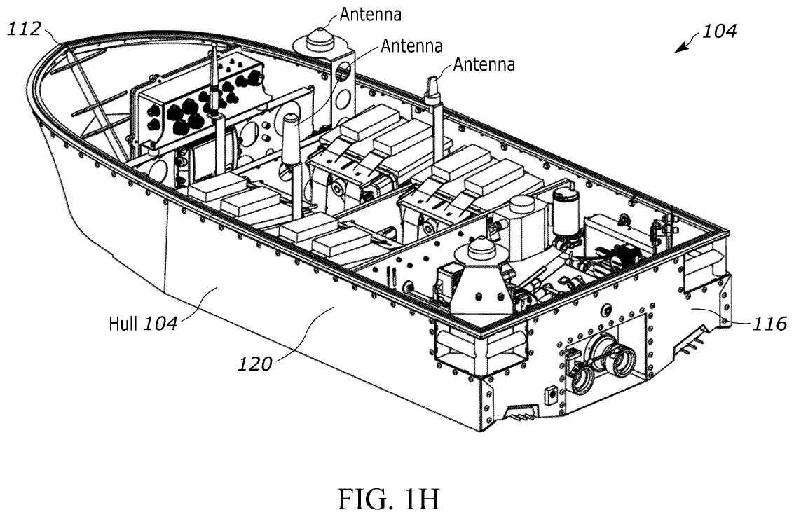

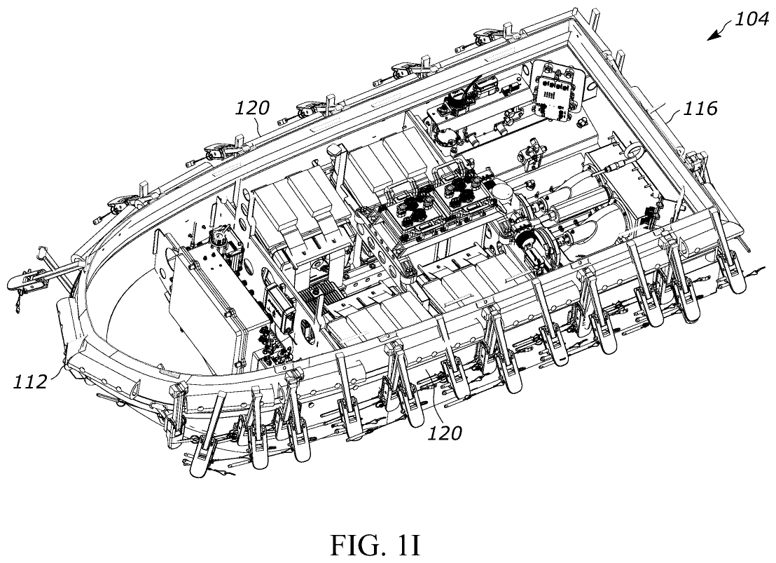

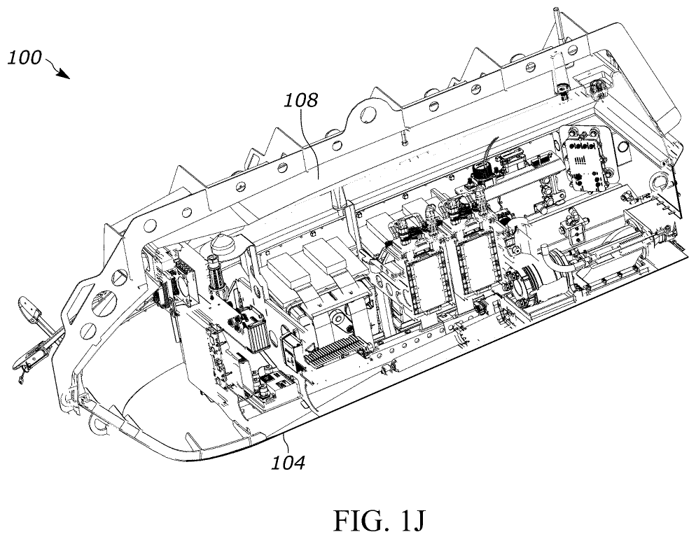

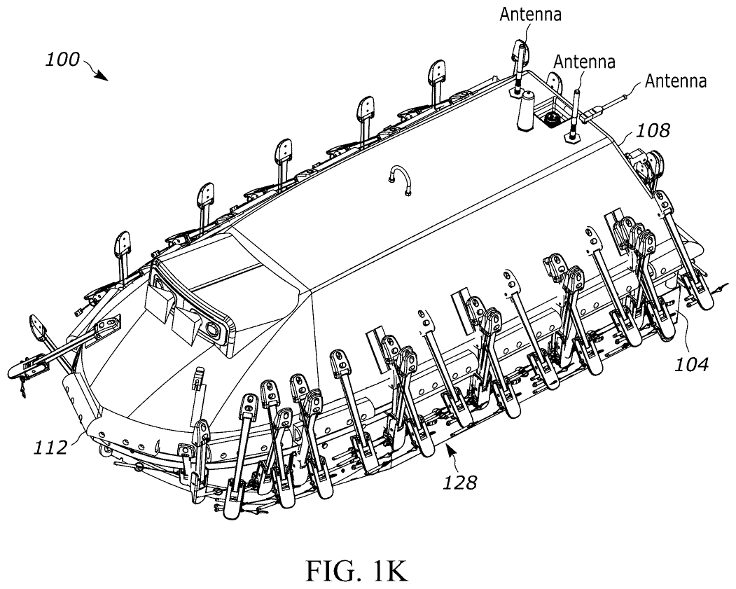

FIGS. 1A-1K illustrate one example of a maritime vehicle 100 constructed in accordance with the teachings of the present disclosure. The maritime vehicle 100 is an unmanned vessel configured to autonomously traverse a body of water. The maritime vehicle 100 generally includes a hull 104 and a cap 108 that is coupled to the hull 104 to secure various components within the maritime vehicle 100. The hull 104 is at least partially disposed in the body of water in which the maritime vehicle 100 is traversing. The hull 104 in this example is a mono-hull that has a front (or bow) 112, a rear (or stern) 116, two sides 120, and a keel 124 coupled to another. The front 112, the rear 116, the sides 120, and the keel 124 can be welded together or can be coupled to one another in a different manner. For example, the front 112, the rear 116, the sides 120, and the keel 124 can be coupled together in the manner described in U.S. Provisional Application No. 63/561,282, titled “Systems and Approaches for Assembling a Maritime Vehicle” and filed Mar. 4, 2024, the contents of which are hereby incorporated by reference herein. The hull 104 is configured such that the hull provides a continuous planning surface that allows the maritime vehicle 100 to be highly maneuverable and to ride along the top of a body of water at high speeds, even in extreme weather conditions and difficult to navigate bodies of water. Meanwhile, the cap 108 is coupled to the hull 104 to cover and/or conceal the components of the maritime vehicle 100 disposed in and carried by the hull 104 as the maritime vehicle 100 traverses the body of water.

In this example, the hull 104 and the cap 108 each have a length that is equal to approximately 6 feet. In other examples, however, the length can vary. For example, the length can be equal to approximately 14 feet. The hull 104 is preferably entirely made of aluminum but can be partially or entirely be made of fiberglass and/or one or more other materials. In other examples, the maritime vehicle 100 can include two or more hulls (e.g., two parallel hulls) instead of the mono-hull. In this example, the cap 108 entirely covers the hull 104 (and the components therein). In other examples, however, the maritime vehicle 100 need not include the cap 108 or the cap 108 may only partially cover the hull 104 (and the components disposed therein).

In some examples, the cap 108 can be removably coupled to the hull 104 via a locking system. For example, as illustrated in FIGS. 1A-1K, the locking system can take the form of a plurality of latch mechanisms 128 disposed around at least a portion (if not the entirety) of a perimeter of the maritime vehicle 100. Thus, the cap 108 can be removed to allow access to the interior of the hull 104. In other examples, however, the cap 108 can be permanently coupled to the hull 104 to permanently conceal the components within the maritime vehicle 100.

The maritime vehicle 100 also includes a plurality of bulkheads 132 arranged within the hull 104. The bulkheads 132 divide the maritime vehicle 100 into a plurality of different compartments for receiving and retaining different components in the maritime vehicle 100.

The maritime vehicle 100 also includes a sensor system that is generally configured to collect data about various components of the maritime vehicle 100 as well as data about the environment surrounding the maritime vehicle 100 (including data about objects in that environment). To this end, the sensor system generally includes a plurality of sensors disposed on an exterior or an interior of the maritime vehicle 100. The sensors can include, for example, one or more pressure sensors (e.g., positioned to detect the pressure of the ambient air external to the maritime vehicle 100, the pressure of the water in which the maritime vehicle 100 is disposed, the pressure within the maritime vehicle 100), one or more temperature sensors (e.g., positioned to measure a temperature of a component of the maritime vehicle 100, a temperature of ambient air external to the maritime vehicle 100, a temperature of water in which the maritime vehicle 100 is disposed), one or more acoustic sensors (e.g., sonar sensors), one or more LIDAR sensors, one or more location sensors (e.g., GPS sensors, compass sensors), one or more motion sensors (e.g., accelerometers, gyroscopes), one or more infrared sensors, one or more water sensors (e.g., a float switch, a capacitive sensor, an ultrasonic sensor, an electrical water sensor, etc.) to determine when water is present and/or present to a given extent (e.g., at a certain volume or level), one or more humidity sensors, one or more power sensors (e.g., configured to detect charging or fueling levels), one or more lighting sensors (e.g., daylight sensors), one or more imaging sensors (e.g., CCD sensors, CMOS sensors), one or more magnetic sensors, or combinations thereof.

The maritime vehicle 100 also includes a power system that is generally configured to power the maritime vehicle 100 (and the components of the maritime vehicle 100). The power system generally includes a thrust system and one or more power sources configured to power the thrust system (and the other components within the maritime vehicle 100). The thrust system is generally configured to propel the maritime vehicle 100 in/on/along the water. The thrust system can be a propeller-based thrust system or can be a jet pump-based thrust system such as the jet pump assembly described in U.S. Provisional Application No. 63/561,166, titled “Jet Pump Assembly for Maritime Vehicle” and filed Mar. 4, 2024, the contents of which are hereby incorporated by reference herein. The one or more power sources can include, for example, one or more batteries, fuel (e.g., gasoline, diesel) stored in tanks carried by the maritime vehicle 100, hydrogen stored in hydrogen tanks carried by the maritime vehicle 100, solar panels (e.g., mounted to an exterior of the vehicle 100), or other sources. The maritime vehicle 100 illustrated in FIGS. 1A-1K includes four battery assemblies each including a rechargeable battery. The maritime vehicle 100 illustrated in FIGS. 1A-1K also includes a retention assembly for the four battery assemblies, e.g., the retention assembly described in U.S. Provisional Application No. 63/561,063, titled “Power System for Maritime Vehicle” and filed Mar. 4, 2024, the contents of which are hereby incorporated by reference herein. The maritime vehicle 100 generally also includes a cooling system configured to cool the thrust system and/or the one or more power sources, thereby preventing these components from overheating and leading to failure of the maritime vehicle 100. For example, the maritime vehicle 100 can include the cooling system described in U.S. Provisional Application No. 63/561,181, titled “Micro-Keel Cooler for Maritime Vehicle” and filed Mar. 4, 2024, the contents of which are hereby incorporated by reference herein.

In operation, the maritime vehicle 100 may be used to deploy and/or retrieve payloads such as, for example, persons, weapons (e.g., drones, missiles, mines, bombs), cargo (e.g., food), scientific instruments, or other equipment. Payloads can be deployed aerially (into the air), underwater, or on the surface of the water. Payloads can also be retrieved from the air, from underwater, or the surface of the water. Payloads to be deployed can be disposed in the hull 104, attached to the exterior surface of the hull 104, or attached to the exterior surface of the cap 108 prior to deployment. Likewise, retrieved payloads can be stored in the hull 104, attached to and stored on the exterior surface of the hull 104, or attached to and stored on the exterior surface of the cap 108.

The maritime vehicle 100 can also include other systems to help with the operation of the maritime vehicle 100, for example a ballast system, a navigation system, and a vision system. The ballast system is generally configured to stabilize the maritime vehicle 100 in the water, regardless of whether the maritime vehicle 100 is stationary or on the move. To this end, the maritime vehicle 100 may include one or more ballast tanks or chambers selectively filled with water or air to vary the buoyancy of the maritime vehicle 100. Alternatively or additionally, the ballast system may include and utilize one or more inflatable devices to vary the buoyancy of the maritime vehicle 100. The ballast system may also provide for the selective submerging and re-surfacing of the maritime vehicle 100 in a similar manner. The navigation system, which may for example be an inertial navigation system, utilizes the sensors of the sensor system to track the position and orientation of the maritime vehicle 100 and to guide the maritime vehicle 100 to its desired location in the body of water (or in a different body of water). The vision system is generally configured to capture, process, and analyze images obtained by the one or more image sensors and other data (e.g., data obtained by other sensors in the sensor system). The vision system can in turn identify or classify the environment surrounding the maritime vehicle 100 (including objects in that environment).

The maritime vehicle 100 further includes a communications system that is generally configured to facilitate communication (i) between the maritime vehicle 100 and one or more central (remote) controllers, (ii) between the maritime vehicle 100 and and/or one or more other maritime vehicles 100 and/or other military assets (e.g., planes, ships), and (iii) between different components of the maritime vehicle 100. The communications system generally includes one or more local controllers and one or more communication modules (e.g., one or more antennae, one or more receivers, one or more transmitters, one or more radios, one or more ethernet switches) to effectuate wired or wireless communication between the maritime vehicle 100 and the central controller(s) or other maritime vehicles 100. For example, the maritime vehicle 100 includes a plurality of antennae disposed on an exterior of the cap 108 as well as a plurality of antennae disposed in the hull 104.

The one or more local controllers are generally configured to communicate data (e.g., operational instructions, data from the sensor system, data from other maritime vehicles 100 or military assets) and to perform automated operations of the maritime vehicle 100 based on that data. In some examples, the maritime vehicle 100 includes a plurality of different local controllers. For example, the maritime vehicle 100 can include one or more thrust controllers (for controlling the operation of the thrust system), one or more sensor controllers (for controlling the sensors in the sensor system), one or more payload controllers (for deploying or retrieving payloads), one or more navigation controllers (as part of the navigation system), and one or more ballast controllers (for controlling the ballast system). It will be appreciated that each of the one or more controllers may be implemented as hardware (e.g., processor, die, integrated device), software (e.g., non-transitory processor readable medium), and/or combinations thereof, in one or more devices (e.g., processor, chip, computer, tablet, mobile device).

While not explicitly described or illustrated herein, it will be appreciated that the maritime vehicle 100 includes several additional components. For example, the maritime vehicle 100 includes various sealing elements configured to provide seals between different components of the vehicle 100 (or between the vehicle 100 and the environment surrounding the vehicle 100). As another example, the maritime vehicle 100 also includes various fasteners that help to couple the components of the maritime vehicle 100 together. As yet another example, the maritime vehicle 100 includes cabling that helps to communicatively couple components of the maritime vehicle 100 together. As yet another example, the maritime vehicle 100 includes various electrical components that help to operate the maritime vehicle 100, e.g., one or more relay boards, one or more DC-DC converters, one or more supervisor boards, and/or one or more brain boards.

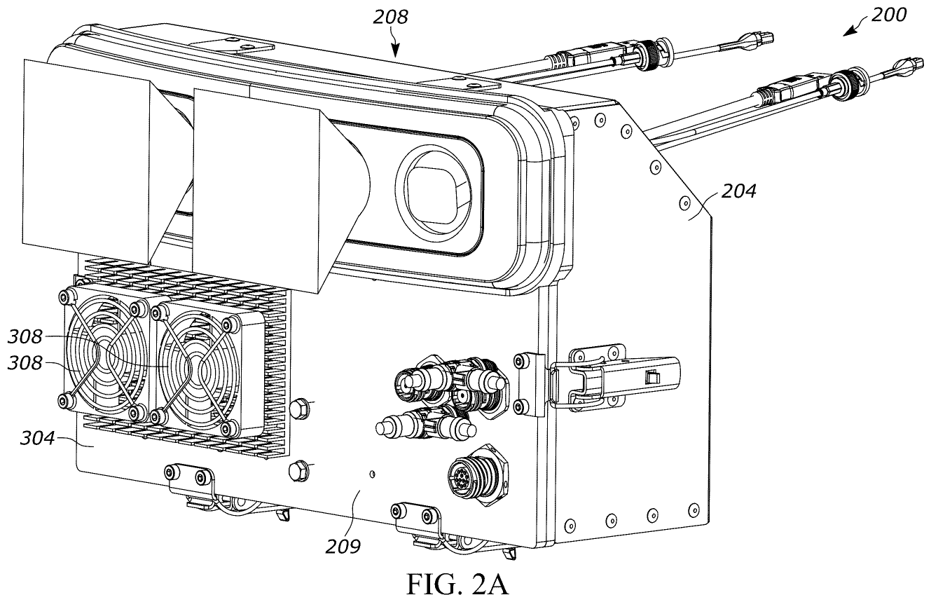

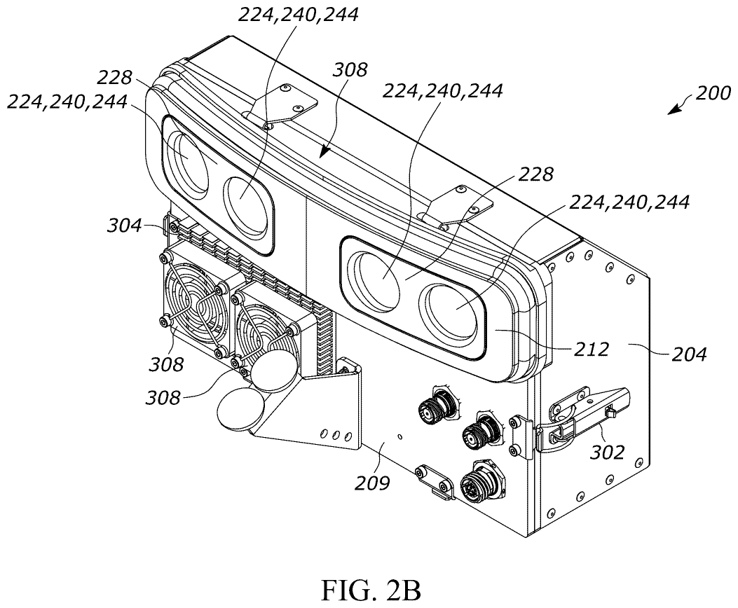

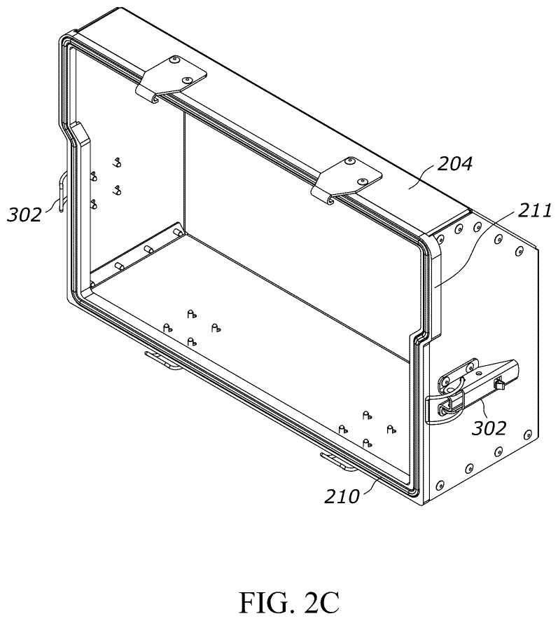

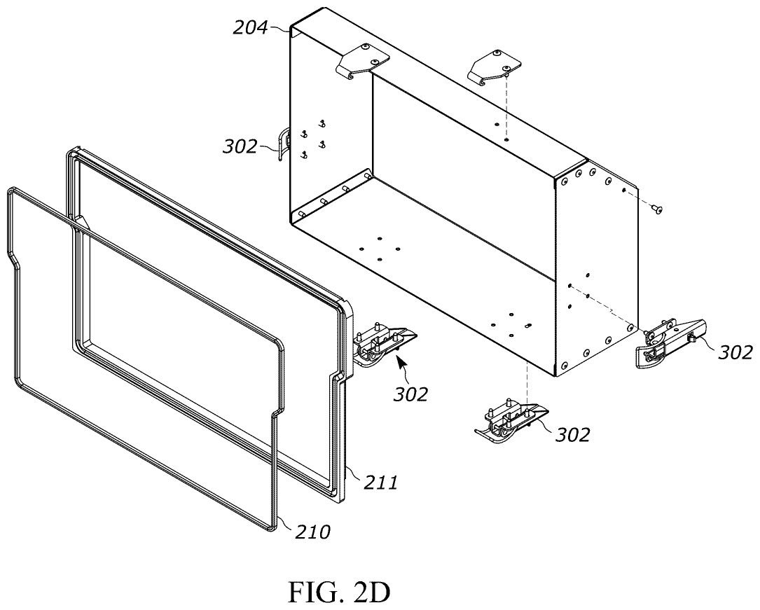

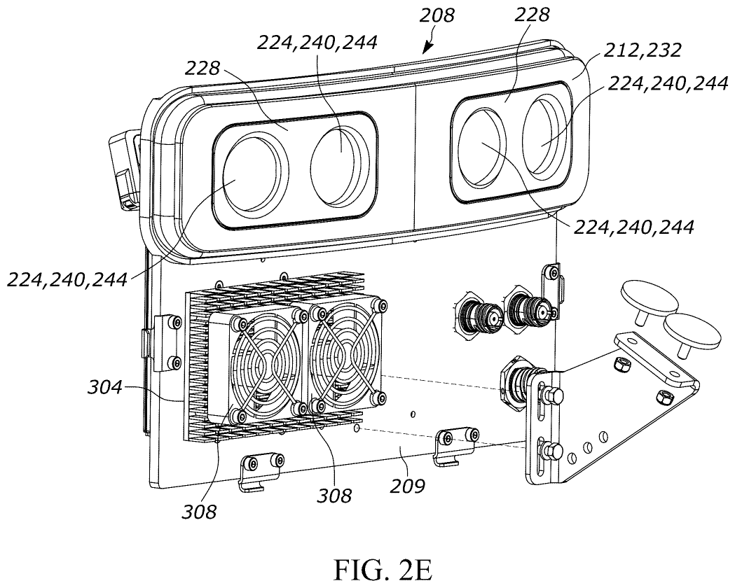

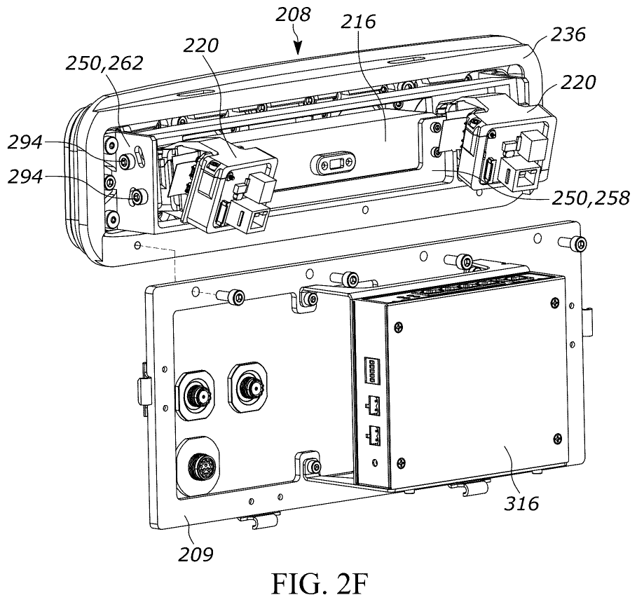

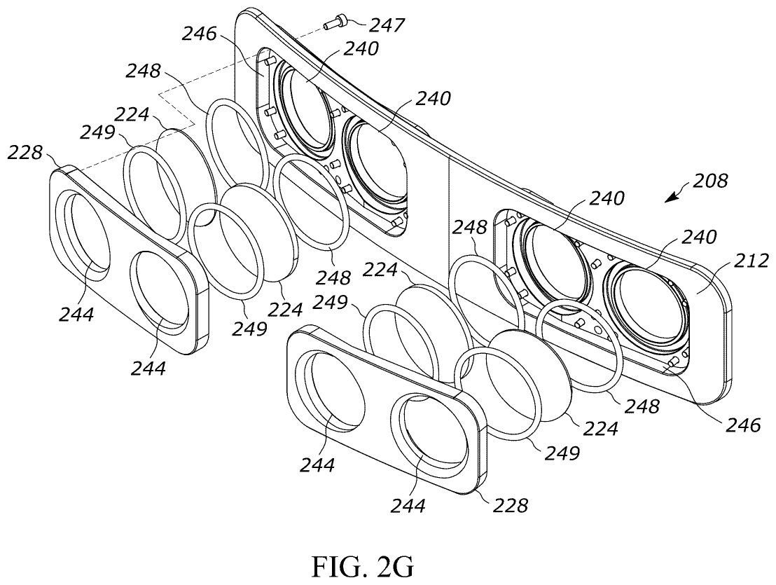

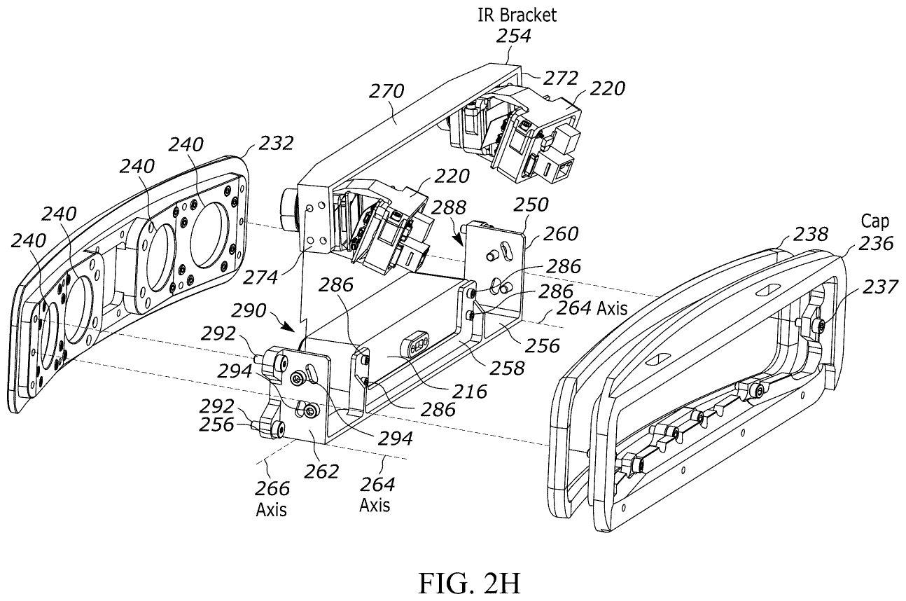

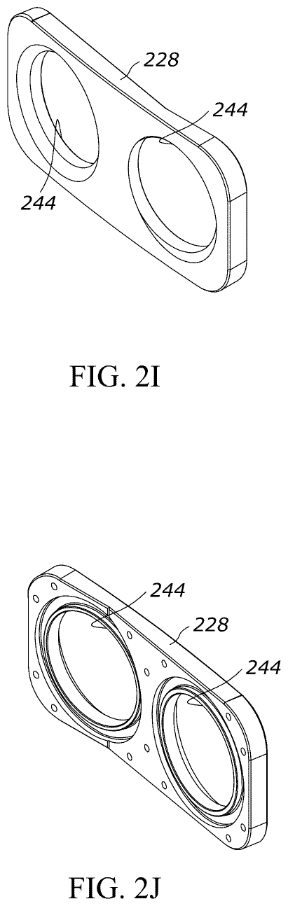

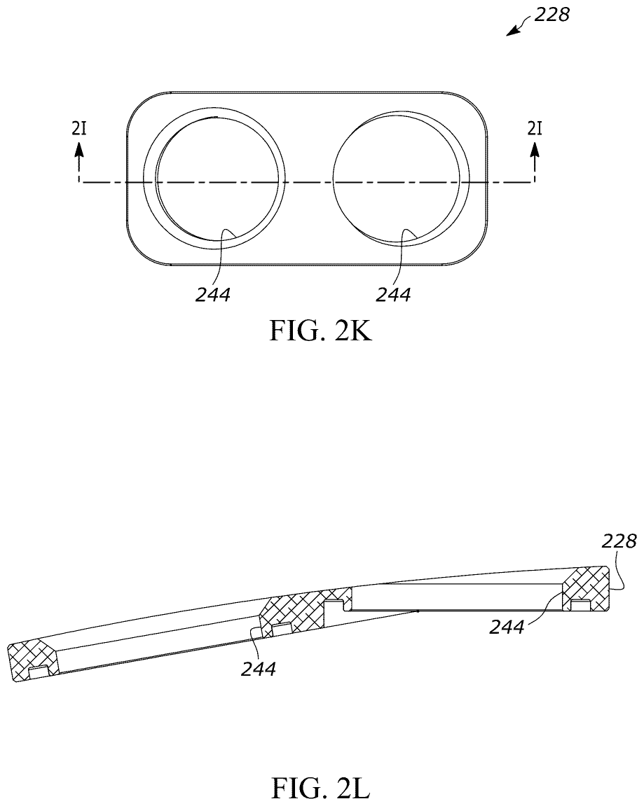

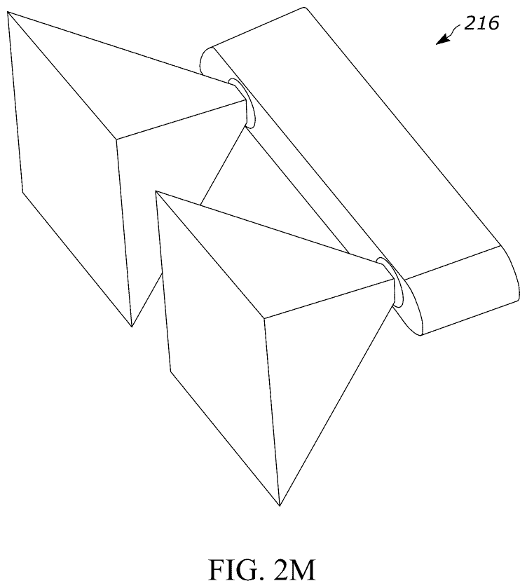

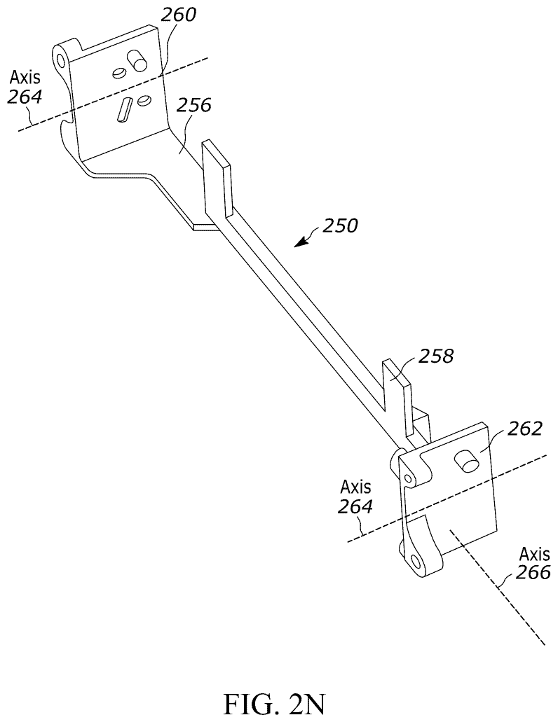

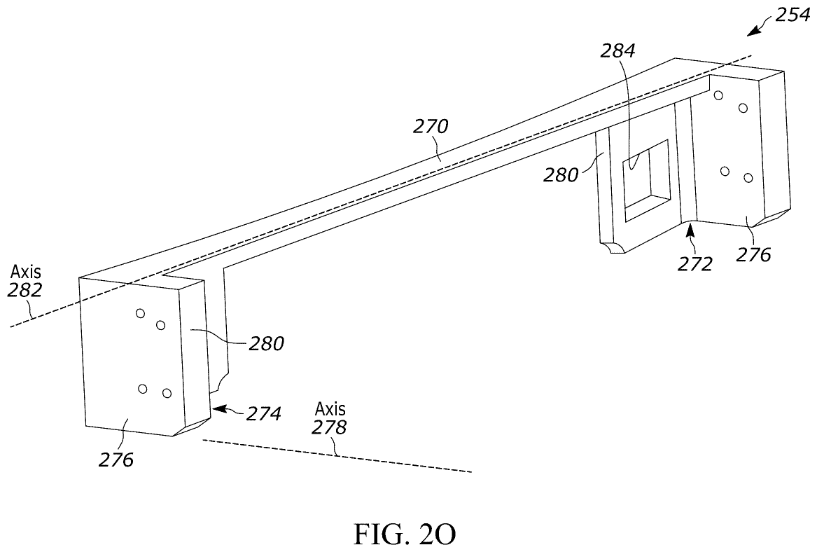

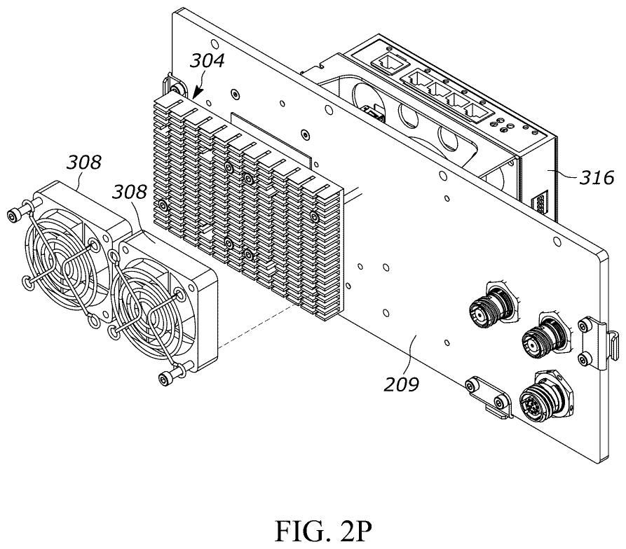

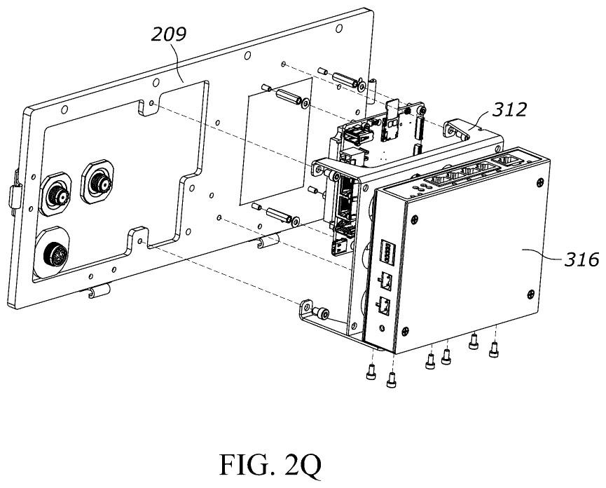

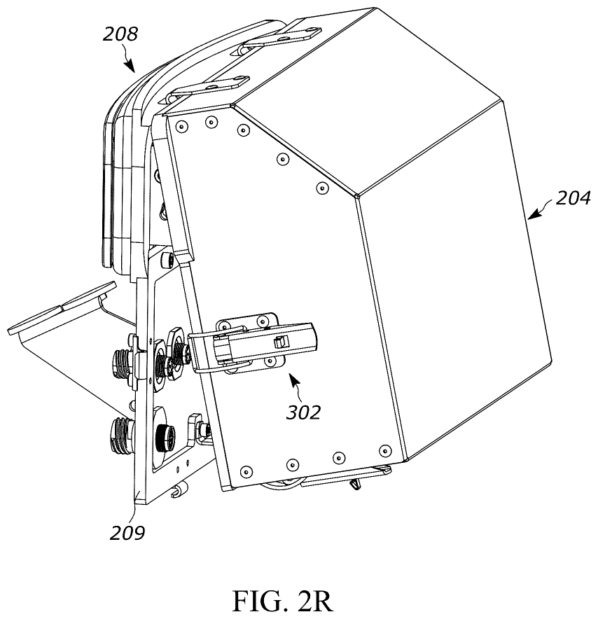

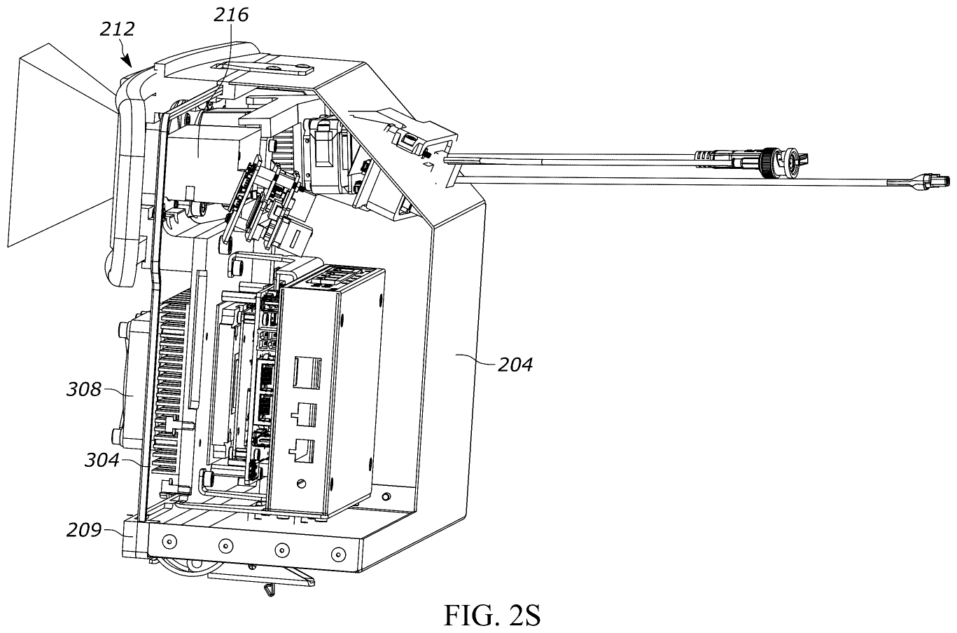

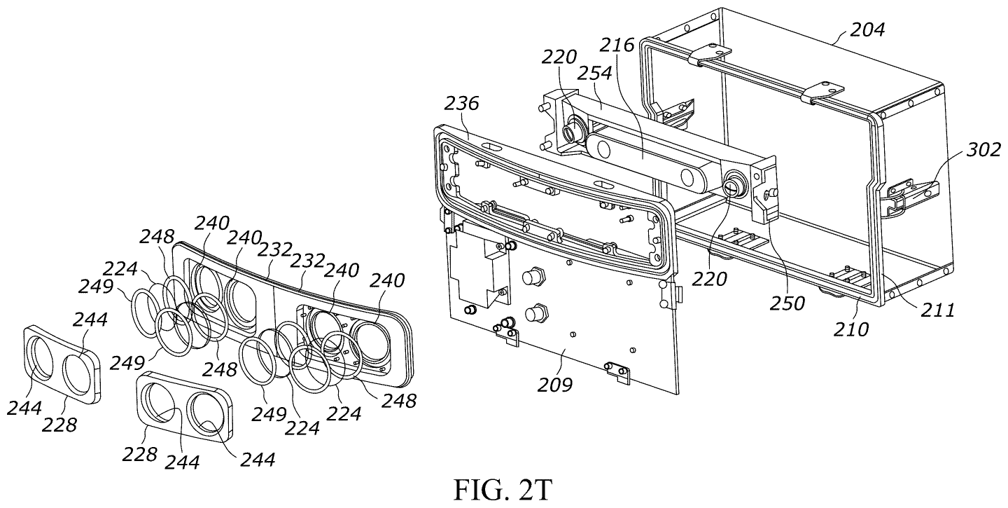

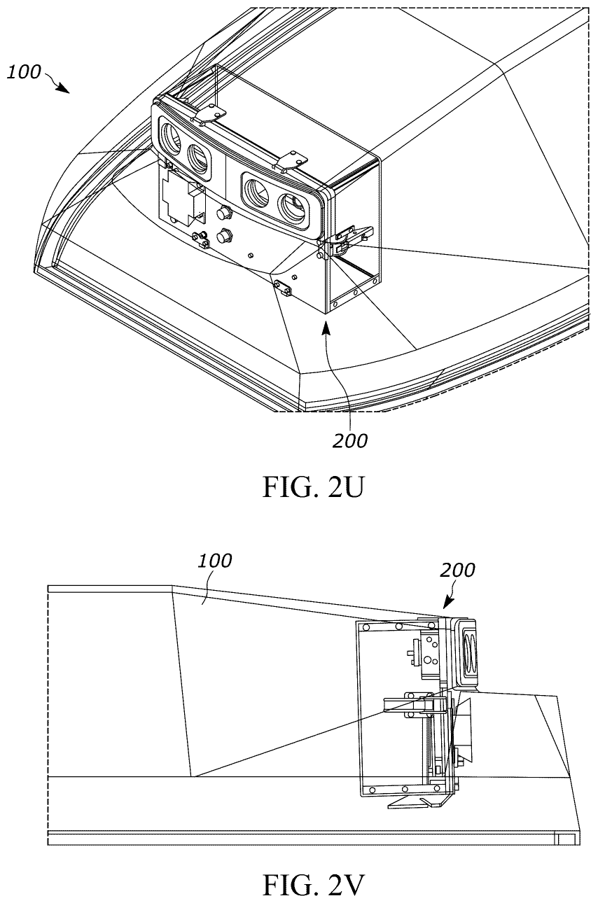

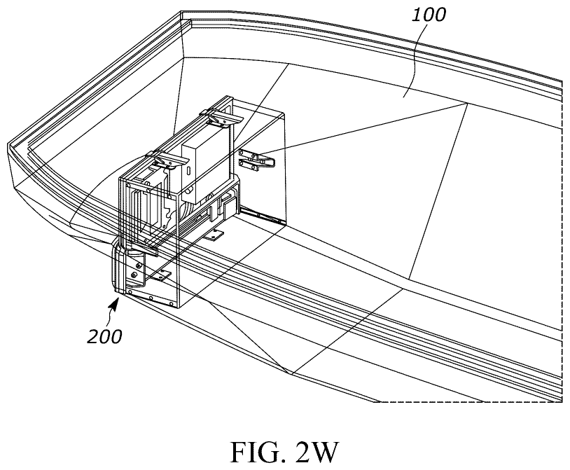

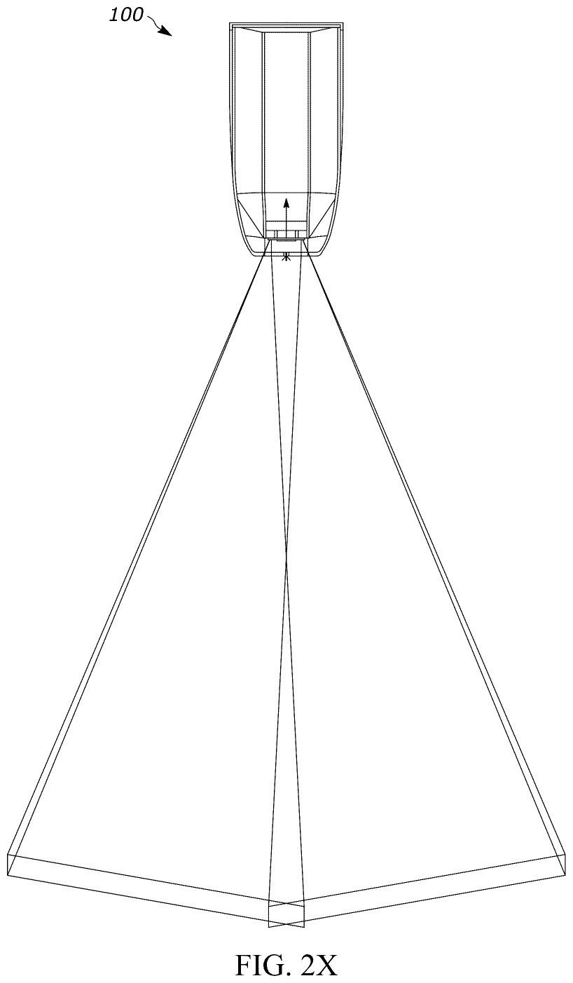

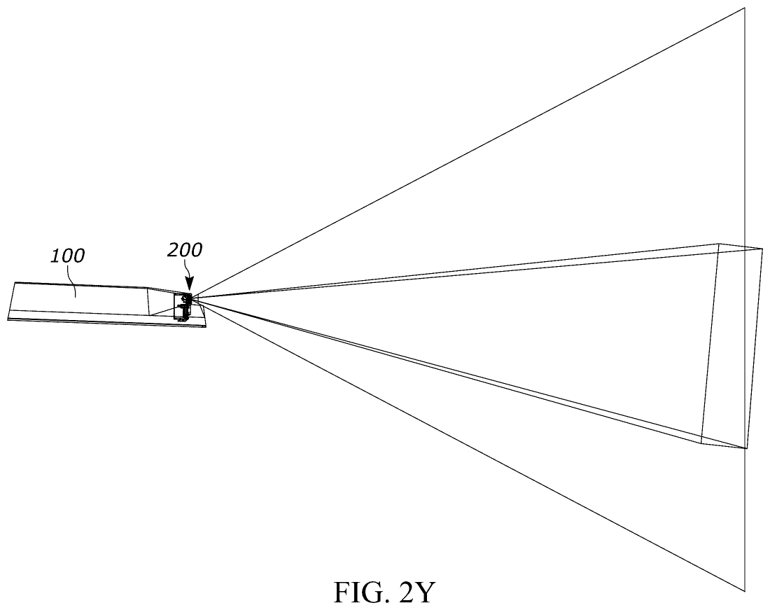

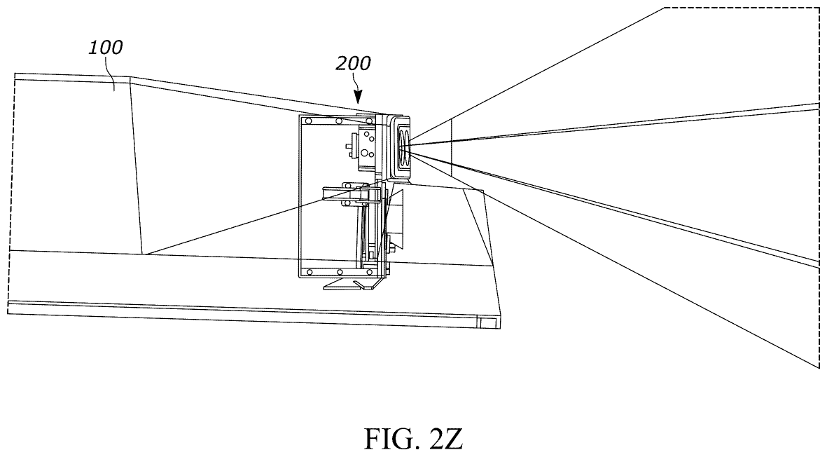

As discussed above, the maritime vehicle 100 can include a vision system. FIGS. 2A-2Z illustrate one example of a vision system 200 that can be employed in the maritime vehicle 100. In this example, the vision system 200 is a stereoscopic vision unit that includes two independent stereoscopic cameras. In this example, the vision system 200 is fully assembled and calibrated before being mounted to a front of the maritime vehicle 100. The vision system 200 can, for example, be sealingly and securely mounted to a front of the hull cap 108 (see, for example, FIGS. 1A and 1K). More particularly, the vision system 200 includes an external element or interface that is bonded with the front of the hull cap 108 as well as one or more seals (e.g., a double o-ring barrel seal) that sealingly couple the external element or interface and the rest of the vision system 200. In this example, the vision system 200 is also removable from the maritime vehicle 100 and can be replaced with another vision system 200 (or a different vision system). In other examples, the vision system 200 can be fully assembled and calibrated while or after being mounted to the front of the maritime vehicle 100. In any event, the vision system 200, so mounted, is optimally positioned to capture, process, and analyze data about the environment surrounding the maritime vehicle 100. Broadly speaking, the vision system 200 is configured to passively detect or sense the presence and/or absence of an object (and/or of any objects, for that matter) within the FOV of the vision system 200 and enable accurate depth (i.e., distance) estimates of such objects using stereoscopic techniques.

The vision system 200 generally includes a housing 204, a camera module 208 coupled to and carried by the housing 204, and an electronics plate 209 coupled to and carried by the housing 204. The housing 204 is configured to be mounted to the maritime vehicle 100, and, more particularly, to the front of the hull cap 108 (see FIGS. 1A and 1K). For example, the housing 204 can include the external element or interface that is bonded with the front of the hull cap 108. The housing 204 is preferably made of fiberglass but can be made of another strong material such that the housing 204 protects the camera module 208 when the maritime vehicle 100 experiences significant shock (e.g., shock values up to 20G), traverses the body of water at high speeds, or is used in dangerous conditions. In some examples, the housing 204 can be purged with nitrogen or dry air for improved performance. Preferably, and as best illustrated in FIGS. 2C, 2D, and 2T, the vision system 200 also includes a first sealing element (e.g., a gasket) 210 and a mount 211 for mounting the first sealing element 210 to the housing 204. In this example, the mount 211 has a substantially rectangular shape and is coupled (e.g., fixedly or removably coupled) to an outer perimeter edge of the housing 204, and the first sealing element 210 has a similar shape as the mount 211 and is removably disposed in a channel formed in the mount 211. When the first sealing element 210 is mounted to the housing 204 via the mount 211, the first sealing element 210 surrounds the interior of the housing 204, such that the first sealing element 210 is arranged to sealingly engage the camera module 208 and the electronics plate 209 and to effect a seal between the housing 204 and the camera module 208 and the electronics plate 209 when the camera module 208 and the electronics plate 209 are coupled to the housing 204. In other words, the first sealing element 210 serves to seal the electrical components within an interior of the housing 204 when the camera module 208 and the electronics plate 209 are coupled to the housing 204.

The camera module 208 generally includes a frame 212, one or more electrical-optical (“EO”) cameras 216, one or more infrared (“IR”) cameras 220, a plurality of windows (or lenses) 224, and a plurality of window retention plates 228 for the windows 224. In this example, the frame 212 is defined by a face plate 232 and a cap 236 coupled to the face plate 232 via a plurality of fasteners 237 (one of which is illustrated in FIG. 2H) and via adhesive (e.g., applied to the rear surface of the face plate 232). In other examples, the face plate 232 and the cap 236 can be coupled together in a different manner. Preferably, the frame 212 also includes a second sealing element 238 (e.g., a gasket) secured to the cap 236 so as to be disposed between the face plate 232 and the cap 236. In this example, the second sealing element 238 is secured in a groove formed in the front surface of the cap 236. The frame 212 also includes a plurality of openings 240 formed in the face plate 232 and sized to receive the windows 224. In this example, the frame 212 includes four openings 240 divided into two pairs of openings. In other examples, however, the frame 212 can include more or less openings 240. Moreover, while not illustrated herein, it will be appreciated that the camera module 208 also generally includes a plurality of covers configured to selectively cover the plurality of windows 224, respectively. The plurality of covers may also cover the plurality of apertures 244 formed in the window retention plates 228.

In this example, the camera module 208 includes a single electrical-optical camera 216 that preferably takes the form of a stereo camera with dual EO image sensors. In this example, the camera module 208 includes two infrared cameras 220. Each of the infrared cameras 220 preferably takes the form of a stereovision IR camera, which may utilize one or more of short wave IR (SWIR), mid-wave IR (MWIR) (cooled or uncooled), and/or long-wave IR (LWIR) (cooled or uncooled) sensors. When the camera module 208 includes pairs of EO/IR cameras 216, 220, each camera may be configured to capture similar electromagnetic radiation across a similar FOV, and may be separated (e.g., fixedly separated) by a baseline distance.

In this example, because the frame 212 includes four openings 240, the camera module 208 includes four windows 224. In this example, each window of the plurality of windows 224 is flat, and each window of the plurality of windows 224 is oriented planar to the EO camera 216 and the IR cameras 220. In other examples, however, one or more of the plurality of windows 224 can be oriented non-planar to the EO camera 216 and/or the IR cameras 220. In this example, each of the windows 224 has an anti-reflection coating. Preferably, the windows positioned in front of the EO camera 216 are formed of a substance that is translucent to visible light, and the windows positioned in front of the IR cameras 220 are formed of a substance that is transparent to one or more IR wavelengths. For example, at least two windows of the plurality of windows 224 may be germanium windows (e.g., manufactured by Edmund Optics). In this example, the camera module 208 includes two window retention plates 228, one window retention plate 228 for each of the pairs of openings 240. Thus, in this example, each of the two retention plates 228 has a pair of apertures 244, each aperture 244 sized and arranged to be aligned with a corresponding one of the openings 240 and a corresponding one of the windows 224 when the two retention plates 228 are coupled to the frame 212. In this example, each of the two retention plates 228 is coupled to the frame 212 by disposing each of the retention plates 228 in one of the mounting cavities 246 formed in the frame 212 and inserting a plurality of fasteners (only one of which is shown in FIG. 2G) through the frame 212 and the respective retention plate 228.

In this example, and as best illustrated in FIGS. 2I-2L, the frame 212 has an outer surface that is curved, creating the appearance that the windows 224 are curved as well (even though they are flat). In this example, each window retention plate 228 has an outer surface that is also curved and is flush with the outer surface of the frame 212 (as well as a surface of the hull cap 108). Further, it will be appreciated that the camera module 208 may also include a plurality of first retaining rings 248 and a plurality of second retaining rings 249. The first retaining rings 248, which in this example take the form of shock-resistant threaded retention rings (e.g., manufactured by Thorlabs, inc.), are seated in a channel formed in the frame 212 at a position surrounding the openings 240, respectively. In turn, the first retaining rings 248 are disposed so as to sealingly engage and retain the rear surface of the windows 224, respectively. Meanwhile, the second retaining rings 249 in this example also take the form of shock-resistant threaded retention rings but are seated in a channel formed in one of the window retention plates 228 at a position surrounding a corresponding one of the apertures 244. In turn, the second retaining rings 249 are disposed so as to sealingly engage and retain the front surface of the windows 224, respectively. Beneficially, the first and second retaining rings 248, 249 are configured to use in connection with windows 224 of different thicknesses, such that windows 224 of different thicknesses can be employed in the vision system 200 as needed.

The camera module 208 also generally includes an EO bracket 250 and an IR bracket 254. As best illustrated in FIGS. 2H and 2N, the EO bracket 250 in this example has a base 256, a camera support 258, a first wall 260, and a second wall 262. The camera support 258 is coupled to and extends outward (upward in FIGS. 2H and 2N) from a central portion of the base 256. As such, the camera support 258 is positioned to receive and support the EO camera 216. The first wall 260 is coupled to and extends outward (upward in FIGS. 2H and 2N) from a first end of the base 256, whereas the second wall 262 is coupled to and extends outward (upward in FIGS. 2H and 2N) from a second end of the base 256. In turn, the second wall 262 is disposed opposite and faces the first wall 260, and each of the first and second walls 260, 262 is oriented along a respective longitudinal axis 264 perpendicular to a transverse axis 266 along which the base 256 is oriented.

Meanwhile, as best illustrated in FIGS. 2H and 20, the IR bracket 254 in this example has a base 270, a first camera support 272, and a second camera support 274. The first camera support 272 is generally configured to receive and support one of the IR cameras 220, whereas the second camera support 272 is generally configured to receive and support the other IR camera 220. More particularly, the first camera support 272 is coupled to a first end of the base 270, whereas the second camera support 272 is coupled to a second end of the base 270 opposite the first camera support 272. Each of the first and second camera supports 272, 274 is defined by a pair of walls, a first wall 276 that is oriented along a respective longitudinal axis 278 and a second wall 280 that is, like the base 270, oriented along a transverse axis 282 that is perpendicular to the longitudinal axes 278. As best illustrated in FIG. 20, the IR bracket 254 in this example also includes a pair of openings 284, one in each of the second walls 280, sized to receive and retain a respective one of the IR cameras 220 therein.

Turning now to FIGS. 2F, 2H, and 2T, the EO camera 216 is coupled to the EO bracket 250 via fasteners 286 disposed in the camera support 258 and the rear side of the EO camera 216. In turn, the EO camera 216 is centrally located in the EO bracket 250, with a first cavity 288 defined between the EO camera 216 and the first wall 260 and a second cavity 290 defined between the EO camera 216 and the second wall 262. The EO bracket 250 is also coupled to the frame 212 so as to retain the EO camera 216 in position immediately adjacent two of the openings 240. In some examples, the EO camera 216 will be fixed in this position, while in other examples, the position of the EO camera 216 can be adjusted as needed. More particularly, in this example, the EO bracket 250 is coupled to the face plate 232 via a plurality of fasteners 292 carried by an outer portion of the EO bracket 250 and inserted into apertures formed in the rear surface of the face plate 232. In other examples, however, the EO bracket 250 can be coupled to the face plate 232 and/or the cap 236 in a different manner.

With reference still to FIGS. 2F, 2H, and 2T, the IR cameras 220 are coupled to the IR bracket 254 such that the IR cameras 220 are carried by and extend outward (downward in FIGS. 2F, 2H, and 2T) from the base 270. In this example, the IR cameras 220 are coupled to the IR bracket 254 by way of the openings 284, through which the IR cameras respectively extend, and a plurality of fasteners (not shown) inserted into a retaining ring (not shown) and apertures formed in the second walls 280 (see FIG. 20). In turn, the IR cameras 220 are located at the first and second ends of the base 270.

As also illustrated in FIGS. 2F, 2H, and 2T, the IR bracket 254 is coupled to the EO bracket 250 such that the IR cameras 220 are coupled to the EO camera 216 in a single unit. In this example, the IR bracket 254 is coupled to the EO bracket 250 by disposing the first and second camera supports 272, 274 in the first and second cavities 288, 290, respectively, and inserting a plurality of fasteners 294 (see FIG. 2H) into a plurality of apertures respectively formed in each of the first walls 276. In turn, the IR bracket 254 is partially disposed in the EO bracket 250, and the IR cameras 220 are disposed in the first and second cavities 288, 290, with the IR cameras 220 substantially horizontally aligned with the EO camera 260 and one IR camera 220 on each side of the EO camera 216, as best illustrated in FIG. 2T. Moreover, the axes 264, 278 will be parallel (or substantially parallel) and the axes 266, 282 will be parallel (or substantially parallel). Further, by virtue of being coupled to the EO bracket 250, the IR bracket 254 is also coupled to the frame 212 and is configured to retain the IR cameras 220 in position immediately adjacent the other two openings 240. In some examples, the IR cameras 220 will be fixed in this position, while in other examples, the position of the IR cameras 220 can be adjusted as needed. It will be appreciated that as referenced herein, objects (e.g., cameras, sensors) may be immediately adjacent to other objects (e.g., openings) without directly contacting them. For example, a sensor may be immediately adjacent to an opening when the edges of the opening do not obscure the FOV of the sensor.

As discussed above, the vision system 200 also includes the electronics plate 209, which is coupled to both the housing 204 and the camera module 208. In this example, the electronics plate 209 is removably coupled to the housing 204 via a plurality of latches 302. In other examples, however, the electronics plate 209 can be removably coupled to the housing 204 in a different manner or can be permanently coupled (e.g., welded) to the housing 204. In this example, the electronics plate 209 includes various electrical components for the camera module 208, including, for example, a heat sink 304 for dissipating heat generated by the electrical components of the vision system 200 (e.g., the camera 216 and/or the cameras 220), one or more fans 308 arranged to direct air into the heat sink 304, an autonomous computer 312, and a communication module 316. The electronics plate 209 can include other electrical or mechanical components as well. In other examples, however, one or more of these electrical components (e.g., the computer 312, the communication module 316) can be located remotely from the vision system 200.

When the camera module 208 is coupled to the housing 204, it will be appreciated that the baseline distance between pairs of the dual EO image sensors and the EO/IR cameras 216, 220 is well-toleranced and is maximized as much as possible. In turn, the delta is consistent and the vision system 200 enables downstream ranging. When the maritime vehicle 100 is in use, and the vision system 200 is operational, the vision system 200 can, for example, have the FOV illustrated in FIG. 2V. Other FOVs are described in greater detail in described in U.S. Provisional Application No. 63/742,533, titled “Perception Hardware Configurations for Maritime Vehicle” and filed Jan. 7, 2025, the contents of which are hereby incorporated by reference herein.

Finally, although certain maritime vehicles have been described herein in accordance with the teachings of the present disclosure, the scope of coverage of this patent is not limited thereto. On the contrary, while the invention has been shown and described in connection with various preferred embodiments, it is apparent that certain changes and modifications, in addition to those mentioned above, may be made. This patent covers all embodiments of the teachings of the disclosure that fairly fall within the scope of permissible equivalents. Accordingly, it is the intention to protect all variations and modifications that may occur to one of ordinary skill in the art.

1. A camera module for a maritime vehicle, the camera module comprising:
a frame comprising first and second openings;
first and second windows disposed in the frame immediately adjacent the first and second openings, respectively;
a retention plate coupled to the frame and configured to retain the first and second windows in the frame immediately adjacent the first and second openings;
a stereo camera disposed within the frame, the stereo camera disposed immediately adjacent the first opening; and
an infrared (IR) camera disposed within the frame, the IR camera disposed immediately adjacent the second opening.

2. The camera module of claim 1, wherein the first and second windows are germanium windows.

3. The camera module of claim 1, wherein the frame has an outer surface that is curved, wherein the retention plate has an outer surface that is curved and is flush with the outer surface of the frame, and wherein the first and second windows are flat.

4. (canceled)

5. The camera module of claim 1, wherein the frame is defined by a face plate and a cap coupled to the face plate, wherein each of the stereo camera and the IR camera is at least partially disposed between the face plate and the cap.

6. The camera module of claim 1, further comprising a stereo bracket coupled to the frame, wherein the stereo camera is carried by the stereo bracket.

7. The camera module of claim 6, further comprising an IR bracket coupled to the frame, wherein the IR camera is carried by the IR bracket.

8. The camera module of claim 7, wherein the IR bracket is coupled to the stereo bracket.

9. The camera module of claim 8, wherein the IR bracket is partially disposed in the stereo bracket such that the IR camera is horizontally aligned with the stereo camera.

10. The camera module of claim 1, wherein the retention plate is disposed in a mounting cavity formed in a front side of the frame.

11. The camera module of claim 1, further comprising a retaining ring configured to secure the IR camera to the frame.

12. The camera module of claim 1, wherein the stereo camera includes a first electro-optical (EO) image sensor disposed immediately adjacent the first opening and a second EO image sensor disposed immediately adjacent a third opening formed in the frame.

13. The camera module of claim 1, wherein the IR camera is a passive camera excluding any active emission system.

14. A camera module for a maritime vehicle, the camera module comprising:
a frame comprising first and second openings;
first and second windows disposed in the frame immediately adjacent the first and second openings, respectively;
a retention plate coupled to the frame and configured to retain the first and second windows in the frame immediately adjacent the first and second openings; and
a stereo camera disposed within the frame, the stereo camera including a first electro-optical (EO) image sensor disposed immediately adjacent the first opening and a second EO image sensor disposed immediately adjacent the second opening.

15. (canceled)

16. The camera module of claim 14, wherein the frame has an outer surface that is curved, wherein the retention plate has an outer surface that is curved and is flush with the outer surface of the frame, and wherein the first and second windows are flat.

17. (canceled)

18. The camera module of claim 14, wherein the frame is defined by a face plate and a cap coupled to the face plate, wherein the stereo camera is at least partially disposed between the face plate and the cap.

19. The camera module of claim 14, further comprising a stereo bracket coupled to the frame, wherein the stereo camera is carried by the stereo bracket.

20. The camera module of claim 14, further comprising:
an infrared (IR) camera disposed within the frame, the IR camera disposed immediately adjacent a third opening formed in the frame; and
an IR bracket coupled to the frame, wherein the IR camera is carried by the IR bracket.

21. (canceled)

22. (canceled)

23. (canceled)

24. A vision system for a maritime vehicle, comprising:
a housing adapted to be mounted to a hull of the maritime vehicle; and
a camera module carried by the housing;
a frame comprising first and second openings;
first and second windows disposed in the frame immediately adjacent the first and second openings, respectively;
a retention plate coupled to the frame and configured to retain the first and second windows in the frame immediately adjacent the first and second openings;
a stereo camera disposed within the frame, the stereo camera disposed immediately adjacent the first opening; and
an infrared (IR) camera disposed within the frame, the IR camera disposed immediately adjacent the second opening.

25. The vision system of claim 24, wherein the housing is a fiberglass housing.

26. (canceled)

27. The vision system of claim 24, wherein the frame has an outer surface that is curved, [and] wherein the retention plate has an outer surface that is curved and is flush with the outer surface of the frame, and wherein the first and second windows are flat.

28. (canceled)

29. The vision system of claim 24, wherein the frame is defined by a face plate and a cap coupled to the face plate, wherein each of the stereo camera and the IR camera is at least partially disposed between the face plate and the cap.

30. The vision system of claim 24, further comprising: a stereo bracket coupled to the frame, wherein the stereo camera is carried by the stereo bracket; and an IR bracket coupled to the frame and to the stereo bracket, wherein the IR camera is carried by the IR bracket.

31. (canceled)

32. (canceled)

33. (canceled)

34. The vision system of claim 24, further comprising: an electronics plate coupled to the camera module; and a heat sink coupled to the electronics plate at a position adjacent the first and second openings.

35. (canceled)

36. (canceled)

37. (canceled)

38. (canceled)

39. A maritime vehicle, comprising:
a hull;
a hull cap coupled to the hull;
a housing sealingly mounted to a front portion of the hull cap; and
a camera module carried by the housing;
a frame comprising first and second openings;
first and second windows disposed in the frame immediately adjacent the first and second openings, respectively;
a retention plate coupled to the frame and configured to retain the first and second windows in the frame immediately adjacent the first and second openings;
a stereo camera disposed within the frame, the stereo camera disposed immediately adjacent the first opening; and
an infrared (IR) camera disposed within the frame, the IR camera disposed immediately adjacent the second opening.

40. The maritime vehicle of claim 39, wherein the housing is a fiberglass housing.

41. (canceled)

42. The maritime vehicle of claim 39, wherein the frame has an outer surface that is curved, wherein the retention plate has an outer surface that is curved and is flush with the outer surface of the frame, and wherein the first and second windows are flat.

43. (canceled)

44. (canceled)

45. The maritime vehicle of claim 39, further comprising: a stereo bracket coupled to the frame, wherein the stereo camera is carried by the stereo bracket; and an IR bracket coupled to the frame and to the stereo bracket, wherein the IR camera is carried by the IR bracket.

46. (canceled)

47. (canceled)

48. (canceled)

49. (canceled)

50. (canceled)

51. (canceled)

52. (canceled)
